(19) United States
(12) Patent Application Publication
(10) Pub. No.: US 2008/0100201 A1
(43) Pub. Date: May 1, 2008

(54) ORGANIC ELECTROLUMINESCENCE DEVICE AND FABRICATING METHOD THEREOF

(75) Inventors: An-Chi Wei, Keelung City (TW); Bo-Ru Yang, Taipei County (TW); Han-Ping Shieh, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: CHUNGHWA PICTURE TUBES, LTD., Taipei (TW)

(21) Appl. No.: 11/554,604

(22) Filed: Oct. 31, 2006

(51) Int. Cl. H01L 51/50; H05B 33/00

(52) U.S. Cl. 313/503; 313/509; 445/24; 313/512

(57) ABSTRACT

An organic electroluminescence (OEL) device, having a polymeric substrate, a plurality of light enhanced structures, an anti-oxidation layer, a first electrode, an organic light emitting layer, a second electrode and a protective layer, is provided. The polymeric substrate has a first surface and a second surface. The light enhanced structures are disposed on the first surface. The anti-oxidation layer is disposed on the second surface. The first electrode is disposed on the anti-oxidation layer. The organic light emitting layer is disposed on the first electrode. The second electrode is disposed on the organic light emitting layer. The protective layer is disposed on the second electrode. Since the OEL device has light enhanced structures, not only light efficiency can be improved but also surface scattering is reduced. Moreover, a method of fabricating an OEL device is also provided to make the OEL device in mass production for lowering the production cost.

### BACKGROUND OF THE INVENTION

1. Field of Invention

The present invention relates to a light emitting device and a fabricating method thereof, and more particularly to an organic electroluminescence (OEL) device and a fabricating method thereof.

2. Description of Related Art

The OEL device has the features such as self luminescence, wide visual angle, high reply speed, low driving voltage and full color, and recently it may be utilized to be applied in the organic electroluminescence display. Generally speaking, the OEL device comprises an anode, a cathode and an organic light emitting layer located between the two electrodes. When the current passes between the anode and the cathode, and the electrons and the electron holes are combined in the organic light emitting layer to generate the excitons, the organic light emitting layer may generate the light emitting mechanism of different colors according to the material features.

In order to increase the ray utilization efficiency of the OEL device, usually another light enhanced layer is further disposed. FIG. 1 is a schematic view of a conventional OEL device. Referring to FIG. 1, the OEL device 100 comprises a glass substrate 110, an anode 120, an organic light emitting layer 130, a cathode 140, a cover plate 150 and a light enhanced layer 160. Particularly, the ray 132 emitted from the organic light emitting layer 130 may be enhanced through the light enhanced layer 160, so as to increase the ray utilization efficiency.

However, in the process of fabricating the OEL device 100 as shown in FIG. 1, the light enhanced layer 160 is adhered to the cover plate 150, thus an air gap 170 is generally generated between the cover plate 150 and the light enhanced layer 160. Therefore, a part of the ray 132 may generate the unnecessary scattering because of the influence of the air gap 170, thus reducing the light enhancing effect of the light enhanced layer 160. In order to solve the problem, in the prior art, mostly a refraction index matching glue (not shown) is used to fill in the air gap 170, or a microlens array is disposed to improve the ray utilization efficiency.

FIG. 2 is a schematic view of another conventional OEL device. Referring to FIG. 2, the OEL device 200 comprises a glass substrate 210, an anode 220, an organic light emitting layer 230, a cathode 240 and a cover plate 250. It should be noted that in the method of fabricating the OEL device 200, firstly a microlens array 212 is fabricated on the glass substrate 210 by reactive ion etching (RIE). Next, the components such as the anode 220, the organic light emitting layer 230, the cathode 240 and the cover plate 250 are fabricated on the glass substrate 210.

To sum up, because the microlens array 212 is disposed on the light exit path, the ray utilization efficiency of the OEL device 200 is increased. However, the process of fabricating the microlens array 212 on the glass substrate 210 by RIE is complicated, so it is not good for the mass production of the OEL device 200, and it is not good for reducing the production cost either.

### SUMMARY OF THE INVENTION

Accordingly, an objective of the present invention is to provide an OEL device, so as to improve the light emitting effect, solve the problem of light scattering, and reduce the production cost.

Another objective of the present invention is to provide a method of fabricating the OEL device, so as to solve the problem of generating the air gap between the film layers, and reduce the production cost.

In order to achieve the above or other objectives, the present invention provides an OEL device, which comprises a polymeric substrate, a plurality of light enhanced structures, an anti-oxidation layer, a first electrode, an organic light emitting layer and a second electrode. The polymeric substrate has a first surface and a second surface. The light enhanced structures are disposed on the first substrate. The anti-oxidation layer is disposed on the second surface. The first electrode is disposed on the anti-oxidation layer. The organic light emitting layer is disposed on the first electrode. The second electrode is disposed on the organic light emitting layer.

In an embodiment of the present invention, the light enhanced structures and the polymeric substrate are integrated as one piece.

In an embodiment of the present invention, the material of the anti-oxidation layer is one selected from among oxide, nitride, photo-resist, epoxy, parylene and the combination thereof.

In an embodiment of the present invention, the material of the polymeric substrate is a moldable polymeric material.

In an embodiment of the present invention, the material of the polymeric substrate is one selected from among polymethyl methacrylate (PMMA, acrylic), polydimethylsiloxane (PDMS), polyimide, poly carbonate (PC), polystyrene (PS), polyethylene terephthalate (PET) and the combination thereof.

In an embodiment of the present invention, the OEL device further comprises a protective layer disposed on the second electrode, and the material of the protective layer is one selected from among glass, metal, polymer and the combination thereof.

In an embodiment of the present invention, the OEL device further comprises a sealant wrapping the organic light emitting layer.

In an embodiment of the present invention, the material of the first electrode comprises transparent conductive material, and the transparent conductive material is, for example, indium tin oxide (ITO), indium zinc oxide (IZO) or thin-metal with the thickness in nano-scale.

In an embodiment of the present invention, the material of the second electrode comprises metal.

In order to achieve the above or other objectives, the present invention further provides an OEL device, which comprises a substrate, a first electrode, an organic light emitting layer, a second electrode, a polymeric substrate, a plurality of light enhanced structures and an anti-oxidation layer. The first electrode is disposed on the substrate. The organic light emitting layer is disposed on the first electrode. The second electrode is disposed on the organic light emitting layer. The polymeric substrate is disposed above the second electrode, and the polymeric substrate has a first surface and a second surface, and the first surface is opposite to the second electrode. The light enhanced structures are disposed on the second surface. The anti-oxidation layer is disposed on the first surface or the second surface.

In an embodiment of the present invention, the light enhanced structures and the polymeric substrate are integrated as one piece.

In an embodiment of the present invention, when the anti-oxidation layer is disposed on the first surface, the OEL device further comprises a buffer layer disposed between the anti-oxidation layer and the second electrode. The material of the buffer layer is, for example, one selected from among oxide, nitride, photo-resist, epoxy, parylene and the combination thereof.

In an embodiment of the present invention, when the anti-oxidation layer is disposed on the second surface and covers the light enhanced structures, the polymeric substrate is located on the second electrode.

In an embodiment of the present invention, when the anti-oxidation layer is disposed on the second surface and covers the light enhanced structures, the OEL device further comprises a buffer layer disposed between the polymeric substrate and the second electrode. The material of the buffer layer is for example one selected from among oxide, nitride, photo-resist, epoxy, parylene and the combination thereof.

In an embodiment of the present invention, the material of the anti-oxidation layer is one selected from among oxide, nitride, photo-resist, epoxy, parylene and the combination thereof.

In an embodiment of the present invention, the material of the polymeric substrate is a moldable polymeric material.

In an embodiment of the present invention, the material of the polymeric substrate is one selected from among PMMA, PDMS, polyimide, poly carbonate (PC), polystyrene (PS), polyethylene terephthalate (PET) and the combination thereof.

In an embodiment of the present invention, the OEL device further comprises a sealant wrapping the organic light emitting layer.

In an embodiment of the present invention, the material of the first electrode comprises metal.

In an embodiment of the present invention, the material of the second electrode comprises the transparent conductive material. The transparent conductive material comprises ITO, IZO or thin-metal with the thickness in nano-scale.

In order to achieve the above or other objectives, the present invention further provides a method of fabricating the OEL device, which comprises providing a polymeric substrate having a first surface and a second surface, wherein a plurality of light enhanced structures is formed on the first surface; forming an anti-oxidation layer on the second surface; forming a first electrode on the anti-oxidation layer; forming an organic light emitting layer on the first electrode; and forming a second electrode on the organic light emitting layer.

In an embodiment of the present invention, the method of forming the light enhanced structures on the first surface comprises molding method or injection molding method.

In an embodiment of the present invention, the method of forming the anti-oxidation layer on the second surface comprises coating method or evaporation method.

In an embodiment of the present invention, the method of fabricating the OEL device further comprises forming a protective layer on the second electrode.

In an embodiment of the present invention, the method of fabricating the OEL device further comprises providing a sealant to wrap the organic light emitting layer.

In order to achieve the above or other objectives, the present invention further provides a method of fabricating the OEL device, which comprises providing a substrate; forming a first electrode on the substrate; forming an organic light emitting layer on the first electrode; forming a second electrode on the organic light emitting layer; providing a polymeric substrate disposed above the second electrode, wherein the polymeric substrate has a first surface and a second surface, the first surface is opposite to the second electrode, and a plurality of light enhanced structures is formed on the second surface; and forming an anti-oxidation layer on the first surface or the second surface.

In an embodiment of the present invention, the method of providing the polymeric substrate comprises forming a polymeric material layer on the substrate; and pressing the polymeric material layer with a mold to form the light enhanced structures on the second surface.

In an embodiment of the present invention, when the anti-oxidation layer is formed on the first surface, the method of fabricating the OEL device further comprises forming a buffer layer between the anti-oxidation layer and the second electrode.

In an embodiment of the present invention, when the anti-oxidation layer is formed on the second surface, the polymeric substrate is directly disposed on the second electrode.

In an embodiment of the present invention, when the anti-oxidation layer is formed on the second surface, the method of fabricating the OEL device further comprises forming a buffer layer between the polymeric substrate and the second electrode.

In an embodiment of the present invention, the method of fabricating the OEL device further comprises providing a sealant to wrap the organic light emitting layer.

The OEL device of the present invention adopts the polymeric substrate with the light enhanced structures, so the ray utilization efficiency of the polymeric substrate may be increase. Further, the OEL device adopts the anti-oxidation layer, so as to increase the waterproof function of the polymeric substrate. Moreover, the method of fabricating the OEL device of the present invention fabricates the polymeric substrate by molding method or injection molding method. Therefore, the OEL device can be in mass production so as to lower the production cost. Further, in the fabricating process, the method of fabricating the OEL device may prevent the generation of the air gap, thus avoiding the light scattering.

In order to the make aforementioned and other objects, features and advantages of the present invention comprehensible, preferred embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic view of a conventional OEL device.

FIG. 2 is a schematic view of another conventional OEL device.

FIGS. 3A˜3F are schematic sectional views of a flow of fabricating the OEL device of the first embodiment of the present invention.

FIGS. 4A˜4F are schematic sectional views of a flow of fabricating the OEL device of the second embodiment of the present invention.

FIG. 5 is a schematic view of the OEL device of the third embodiment of the present invention.

FIGS. 6A˜6B are schematic views of the steps of providing the polymeric substrate of the fourth embodiment of the present invention.

FIGS. 7A˜7B are schematic sectional views of a part of the flow of fabricating the OEL device of the fifth embodiment of the present invention.

FIGS. 8A˜8B are schematic sectional views of a part of the flow of fabricating the OEL device of the sixth embodiment of the present invention.

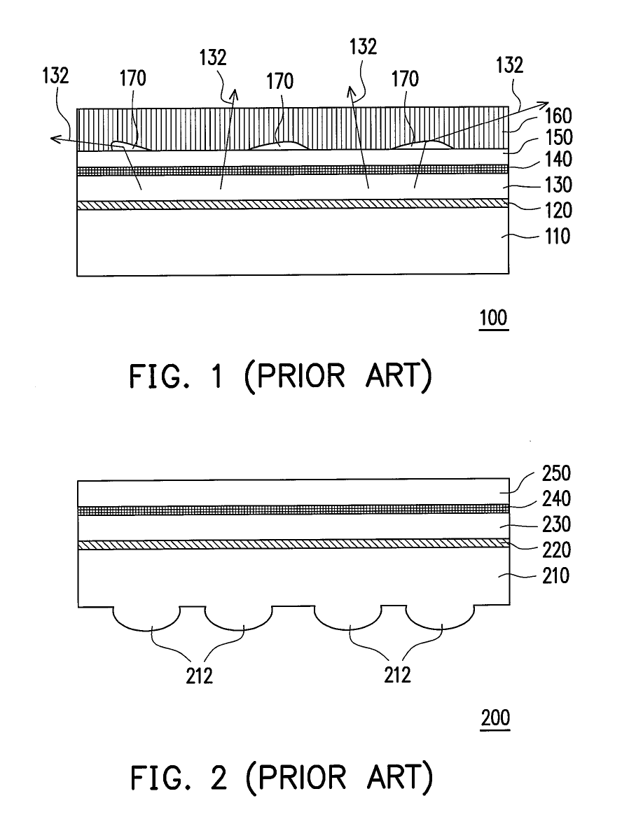

### DESCRIPTION OF EMBODIMENTS

### The First Embodiment

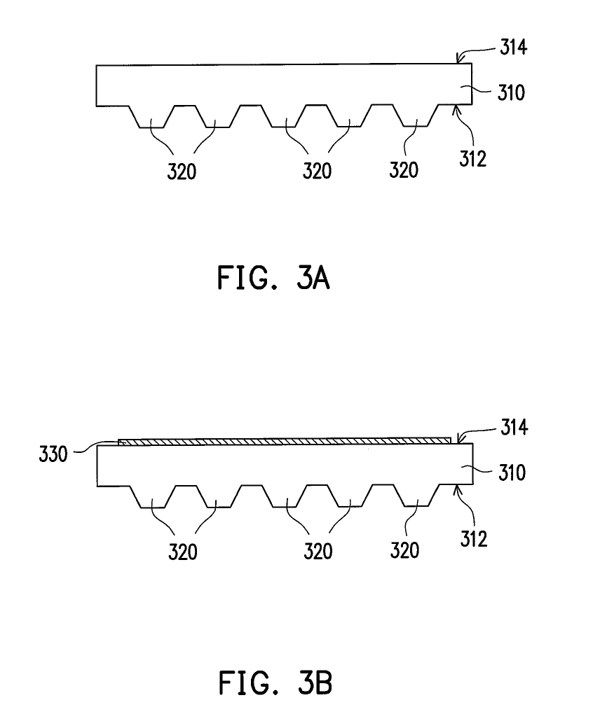

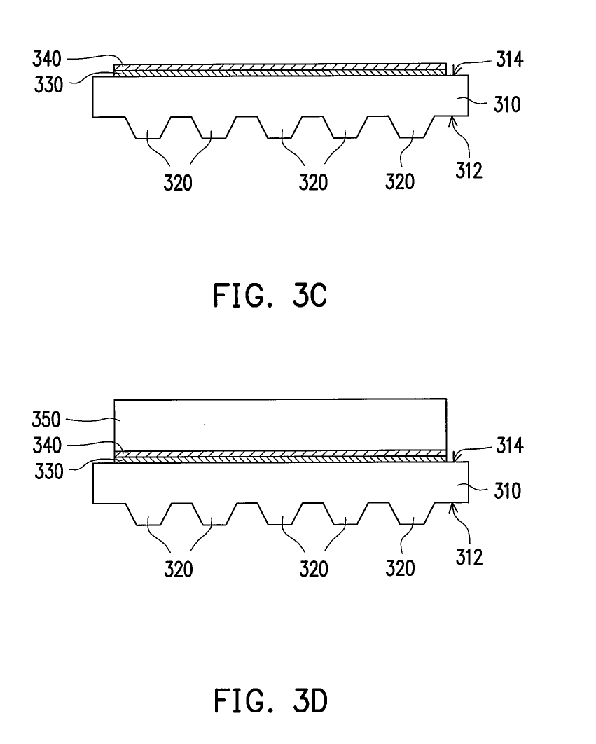

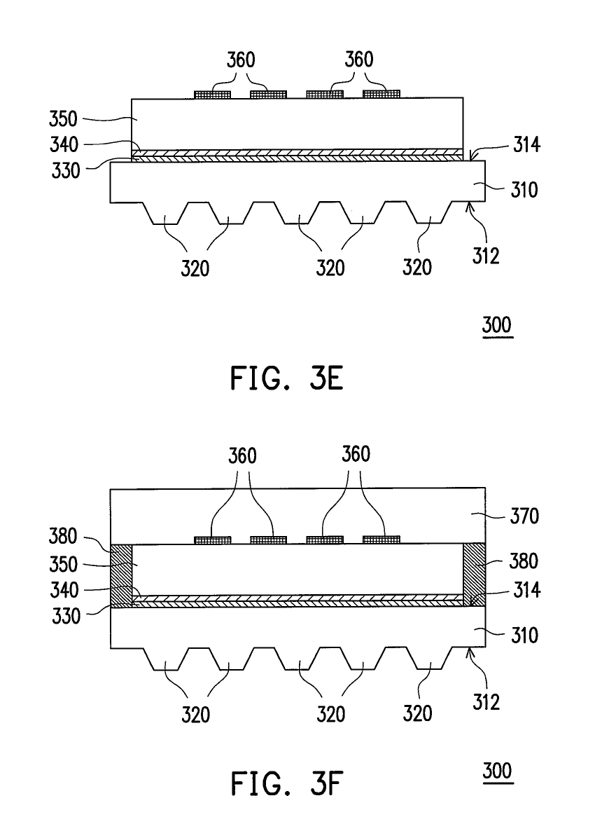

FIGS. 3A˜3F are schematic sectional views of a flow of fabricating the OEL device of the first embodiment of the present invention. The embodiment is about the fabricating of a bottom emission OEL device.

Referring to FIG. 3A, firstly a polymeric substrate 310 having a first surface 312 and a second surface 314 is provided, wherein a plurality of light enhanced structures 320 is formed on the first surface 312. In the present embodiment, the method of forming the light enhanced structures 320 on the first surface 312 may be molding method or injection molding method. Particularly, the light enhanced structures 320 and the polymeric substrate 310 may be the construction that is integrated as one piece. As compared with the method of fabricating the microlens array 212 by RIE as shown in FIG. 2 in the conventional art, it is easier to fabricate the polymeric substrate 310 with the light enhances structures 320, so it can be in mass production so as to lower the production cost.

Moreover, the material of the polymeric substrate 310 as shown in FIG. 3A may be moldable polymeric material, particularly, may be one selected from among PMMA, PDMS, polyimide, poly carbonate (PC), polystyrene (PS), polyethylene tereplithalate (PET) and the combination thereof. Therefore, it is easy to make the shape of the light enhanced structures 320 on the polymeric substrate 310, and the polymeric substrate 310 and the light enhanced structures 320 may be made to be light transmissive.

Next, referring to FIG. 3B, an anti-oxidation layer 330 is formed on the second surface 314. In an embodiment, the method of forming the anti-oxidation layer 330 on the second surface 314 is, for example, coating method, evaporation method or another suitable method, and the material of the anti-oxidation layer 330 is one selected from among oxide, nitride, photo-resist, epoxy, parylene and the combination thereof. Generally speaking, the waterproof function of the polymeric substrate 310 is poor. Therefore, the waterproof function of the polymeric substrate 310 may be improved by disposing the anti-oxidation layer 330.

Then, referring to FIG. 3C, a first electrode 340 is formed on the anti-oxidation layer 330. In an embodiment, the method of forming the first electrode 340 may be sputtering, evaporation method or another suitable method. The material of the first electrode 340 comprises transparent conductive material, and the transparent conductive material is, for example, ITO, IZO or another suitable material.

Then, referring to FIG. 3D, an organic light emitting layer 350 is formed on the first electrode 340. In an embodiment, the method of forming the organic light emitting layer 350 is, for example, coating method, evaporation method or another suitable method, and the type of the organic light emitting layer 350 is not limited in the present invention.

Then, referring to FIG. 3E, a second electrode 360 is formed on the organic light emitting layer 350. The method of forming the second electrode 360 may be sputtering, evaporation method or another suitable method. The material of the second electrode 360 comprises metal, and the type of the metal is not limited in the present invention.

After the fabricating steps as shown in FIGS. 3A˜3E, the bottom emission OEL device 300 as shown in FIG. 3E is formed. The OEL device 300 comprises a polymeric substrate 310, a plurality of light enhanced structures 320, an anti-oxidation layer 330, a first electrode 340, an organic light emitting layer 350 and a second electrode 360. The polymeric substrate 310 has a first surface 312 and a second surface 314. The light enhanced structures 320 are disposed on the first surface 312. The anti-oxidation layer 330 is disposed on the second surface 314. The first electrode 340 is disposed on the anti-oxidation layer 330. The organic light emitting layer 350 is disposed on the first electrode 340. The second electrode 360 is disposed on the organic light emitting layer 350.

Particularly, because the first electrode 340 is of the transparent conductive material, and the second electrode 360 is of the metal material, the ray emitted from the organic light emitting layer 350 may exit downwardly through the polymeric substrate 310. Moreover, the materials and the advantages of all the components are described in the method of fabricating the OEL device 300, which will not be described herein.

Moreover, the method of fabricating the OEL device 300 of the embodiment further comprises forming a protective layer 370 on the second electrode 360, as shown in FIG. 3F. The material of the protective layer 370 is, for example, one selected from among glass, metal, polymer and the combination thereof.

Further, referring to FIG. 3F, the method of fabricating the OEL device 300 of the embodiment further comprises providing a sealant 380 to wrap the organic light emitting layer 350. The material of the sealant 380 may be the UV cure adhesive, thermal cure adhesive or another similar material. Therefore, the OEL device 300 is packaged by using the protective layer 370 and the sealant 380, so as to further avoid the external moisture from entering into the organic light emitting layer 350. As such, the working life of the OEL device 300 is prolonged.

To sum up, in the method of fabricating the OEL device 300 in the first embodiment, the polymeric substrate 310 with the light enhanced structures 320 is fabricated by using molding method or injection molding method, therefore it may be in mass production to lower the production cost of the OEL device 300.

Moreover, the OEL device 300 may improve the ray utilization efficiency by the light enhanced structures 320. Further, by disposing the anti-oxidation layer 330, the waterproof function of the OEL device 300 is effectively improved.

### The Second Embodiment

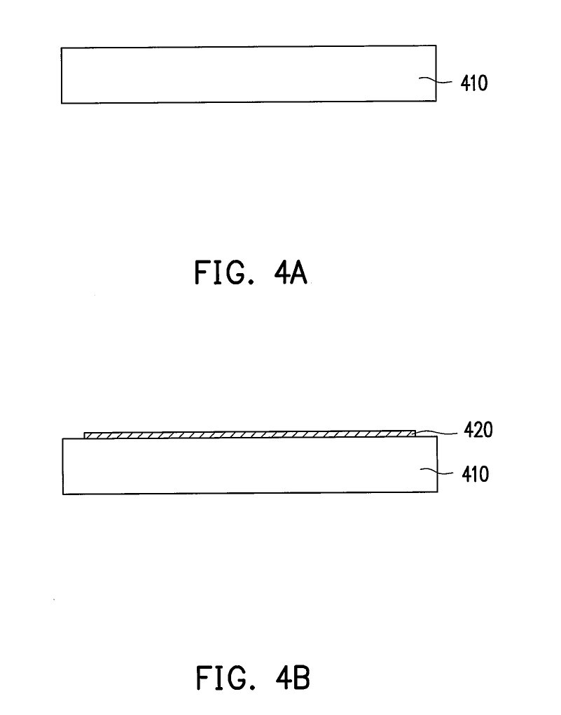

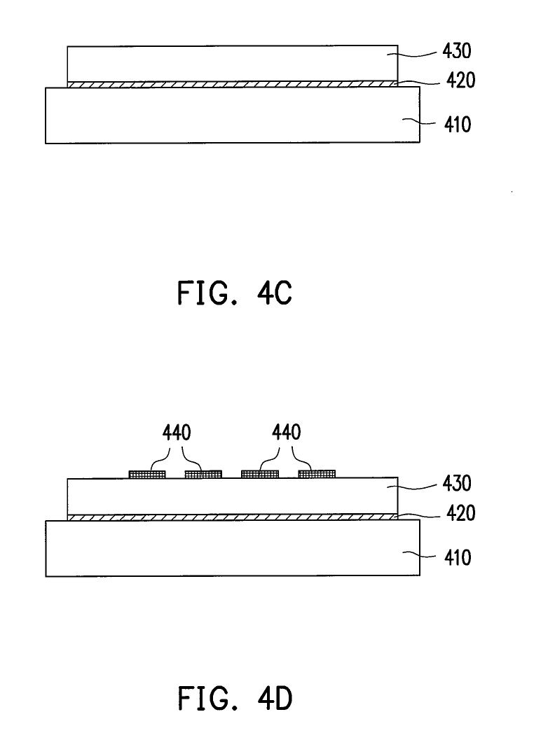

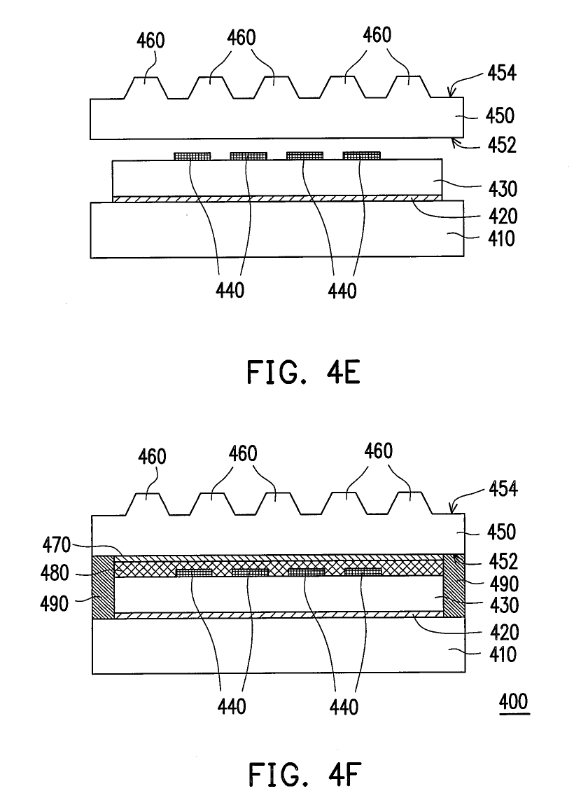

FIGS. 4A˜4F are schematic sectional views of a flow of fabricating the OEL device of the second embodiment of the present invention. The embodiment is about the fabricating of a top emission OEL device.

Referring to FIG. 4A, firstly a substrate 410 is provided. The substrate 410 may be a glass substrate, a plastic substrate or another kind of substrate.

Next, referring to FIG. 4B, a first electrode 420 is formed on the substrate 410. In an embodiment, the method of forming the first electrode 420 may be sputtering, evaporation method or another suitable method. The material of the first electrode 420 is, for example, metal, and the type of the metal is not limited in the present invention.

Then, referring to FIG. 4C, an organic light emitting layer 430 is formed on the first electrode 420. In an embodiment, the method of forming the organic light emitting layer 430 is, for example, coating method, evaporation method or another suitable method, and the type of the organic light emitting layer 430 is not limited in the present invention.

Then, referring to FIG. 4D a second electrode 440 is formed on the organic light emitting layer 430. In an embodiment, the method of forming the second electrode 440 may be sputtering, evaporation method or another suitable method. The material of the second electrode 440 comprises transparent conductive material, and the transparent conductive material is, for example, ITO, IZO, thin-metal with the thickness in nano-scale (e.g. less than 20 nm) or another suitable material.

After that, referring to FIG. 4E, a polymeric substrate 450 is provided, and the polymeric substrate 450 is made to be disposed above the second electrode 440, wherein the polymeric substrate 450 has a first surface 452 and a second surface 454. The first surface 452 is opposite to the second electrode 440, and a plurality of light enhanced structures 460 is formed on the second surface 454. In the present embodiment, the polymeric substrates 450 are components fabricated by molding method or injection molding method. The material of the polymeric substrate 450 has been described in the first embodiment, which will not be described herein.

Referring to FIG. 4F, then, an anti-oxidation layer 470 is formed on the first surface 452. The method of forming the anti-oxidation layer 470 is, for example, coating method or another suitable method, and the material of the anti-oxidation layer 470 is, for example, oxide, nitride, photo-resist, epoxy, parylene or the combination thereof.

In the embodiment, when the anti-oxidation layer 470 is formed on the first surface 452, the method of fabricating the OEL device further comprises forming a buffer layer 480 between the anti-oxidation layer 470 and the second electrode 440. The method of forming the buffer layer 480 is, for example, coating method or another suitable method, and the material of the buffer layer 480 is, for example, one selected from among oxide, nitride, photo-resist, epoxy, parylene and the combination thereof, or other suitable materials. More particularly, by coating the buffer layer 480 on the second electrode 440, the anti-oxidation layer 470 may be prevented from directly contacting with the second electrode 440, so as to avoid the anti-oxidation layer 470 from damaging the second electrode 440.

After the steps of FIGS. 4A˜4F, the top emission OEL device 400 as shown in FIG. 4F is formed. The OEL device 400 comprises a substrate 410, a first electrode 420, an organic light emitting layer 430, a second electrode 440, a polymeric substrate 450, a plurality of light enhanced structures 460 and an anti-oxidation layer 470. The first electrode 420 is disposed on the substrate 410. The organic light emitting layer 430 is disposed on the first electrode 420. The second electrode 440 is disposed on the organic light emitting layer 430. The polymeric substrate 450 is disposed above the second electrode 440, the polymeric substrate 450 has a first surface 452 and a second surface 454, and the first surface 452 is opposite to the second electrode 440. The light enhanced structures 460 are disposed on the second surface 454. The anti-oxidation layer 470 is disposed on the first surface 452. Particularly, in the present embodiment, when the anti-oxidation layer 470 is disposed on the first surface 452, the OEL device 400 further comprises a buffer layer 480 disposed between the anti-oxidation layer 470 and the second electrode 440.

The materials of the components are described in the method of fabricating the OEL device 400, so it will not be described herein. Moreover, referring to FIG. 4F, a sealant 490 may also be used to wrap the organic light emitting layer 430, so as to improve the waterproof function of the OEL device 400.

To sum up, in the method of fabricating the OEL device 400 in the second embodiment, the polymeric substrate 450 with the light enhanced structures 460 is fabricated by using molding method or injection molding method, thus the polymeric substrate 450 may be in mass production so as to lower the production cost of the OEL device 400. Moreover, the light enhanced efficiency of the OEL device 400 is improved by the light enhanced structures 460. By disposing the anti-oxidation layer 470, the waterproof function of the OEL device 400 is effectively improved. Particularly, by disposing the buffer layer 480, the anti-oxidation layer 470 may be avoided from damaging the second electrode 440.

### The Third Embodiment

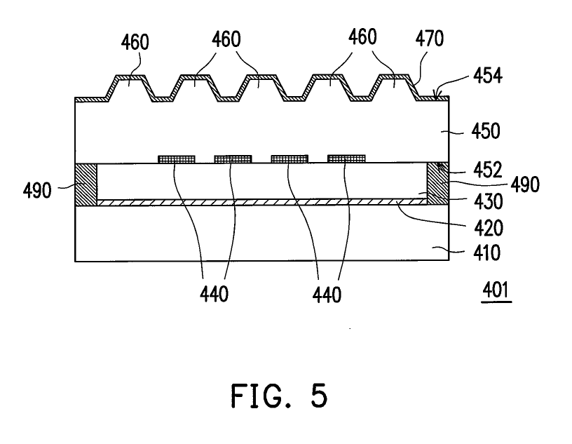

The third embodiment is similar to the second embodiment. It is also about the fabricating method and the structure of a top mission OEL device. FIG. 5 is a schematic view of the OEL device of the third embodiment of the present invention.

Referring to FIGS. 4A˜4E and FIG. 5, firstly, in the third embodiment, the steps as shown in FIGS. 4A˜4D are used to fabricate an OEL device having the substrate 410, the first electrode 420, the organic light emitting layer 430 and the second electrode 440. Then, as shown in FIG. 4E, a polymeric substrate 450 is provided.

It should be noted that the difference between the present embodiment and the second embodiment is that in the third embodiment, the anti-oxidation layer 470 is not formed between the second electrode 440 and the polymeric substrate 450. As shown in FIG. 5, when the anti-oxidation layer 470 is formed on the second surface 454, the polymeric substrate 450 is directly disposed on the second electrode 440.

After the above steps, the OEL device 401 as shown in FIG. 5 is formed, which comprises a substrate 410, a first electrode 420, an organic light emitting layer is 430, a second electrode 440, a polymeric substrate 450, a plurality of light enhanced structures 460 and an anti-oxidation layer 470. The first electrode 420 is disposed on the substrate 410. The organic light emitting layer 430 is disposed on the first electrode 420. The second electrode 440 is disposed on the organic light emitting layer 430. The polymeric substrate 450 is disposed on the second electrode 440, the polymeric substrate 450 has a first surface 452 and a second surface 454, and the first surface 452 is opposite to the second electrode 440. The light enhanced structures 460 are disposed on the second surface 454. The anti-oxidation layer 470 is disposed on the second surface 452. The materials of the components are described above, so it will not be described herein.

Particularly, in the present embodiment, when the anti-oxidation layer 470 is disposed on the second surface 454 and covers the light enhanced structures 460, the polymeric substrate 450 is located on the second electrode 440. In this manner, the fabricating of the buffer layer 480 may be omitted, so as to simplify the structure of the OEL device 401.

Also, the polymeric substrate 450 may serve as the protective layer itself to protect the OEL device 401. Further, the anti-oxidation layer 470 directly covering on the second surface 454 of the polymeric substrate 450 may improve the waterproof function of the polymeric substrate 450, so as to prevent the moisture from damaging the organic light emitting layer 430.

Moreover, referring to FIG. 5, the sealant 490 may also be used to wrap the organic light emitting layer 430 and package the OEL device 401, so as to improve the waterproof function of the OEL device 401.

### The Fourth Embodiment

The fourth embodiment is similar to the third embodiment. The difference between the two is illustrated as follows. In the steps of the third embodiment, the polymeric substrate 450 with the light enhanced structures 460 is fabricated by molding method or injection molding method, as shown in FIG. 4E. However, in the fourth embodiment, the step of providing the polymeric substrate 450 is directly performed on the OEL device.

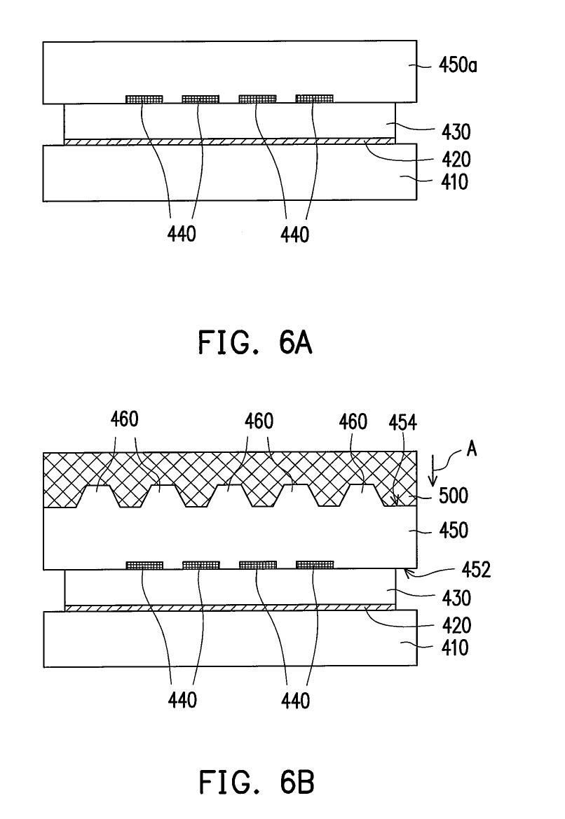

FIGS. 6A˜6B are schematic views of the steps of providing the polymeric substrate of the fourth embodiment of the present invention. Referring to FIGS. 4A˜4D, FIGS. 6A˜6D and FIG. 5, firstly, in the present embodiment, the steps as shown in FIGS. 4A˜4D are used to fabricate the OEL device having the substrate 410, the first electrode 420, the organic light emitting layer 430 and the second electrode 440. Then, the steps of FIGS. 6A˜6D are adopted to directly fabricate the polymeric substrate 450 with the light enhanced structures 460 on the OEL device.

Referring to FIG. 6A, firstly, a polymeric material layer 450a is formed on the substrate 410. The method of forming the polymeric material layer 450a may be coating method, evaporation method or another suitable method, and the material of the polymeric material layer 450a may be moldable polymeric material, more specifically, may be one selected from PMMA, PDMS, polyimide, poly carbonate (PC), polystyrene (PS), polyethylene terephthalate (PET) and the combination thereof, or other suitable materials. It should be noted that the polymeric material layer 450a is fabricated on the OEL device, and covers the second electrode 440.

Then, as shown in FIG. 6B, the polymeric material layer 450a is pressed by using a mold 500, so as to form the light enhanced structures 460 on the second surface 454. The pressing action of the mold 500 is performed along the pressing direction A.

Therefore, in this step, the polymeric substrate 450 with the light enhanced structures 460 is directly formed on the OEL device, and during the process of the pressing action, the air gap (not shown) between each film layer is removed. Therefore, the ray emitted by the organic light emitting layer 430 may not be affected by the air gap, so as to improve the light enhanced efficiency of the OEL device.

Particularly, the anti-oxidation layer 470 is further forined on the polymeric substrate 450, and a sealant 490 is formed to wrap the organic light emitting layer 430, so as to form the OEL device 401 the same as that in FIG. 5. Moreover, the OEL device structure fabricated by the steps is the same as the OEL device of the third embodiment (as shown in FIG. 5), so the components and the materials are not illustrated again here.

### The Fifth Embodiment

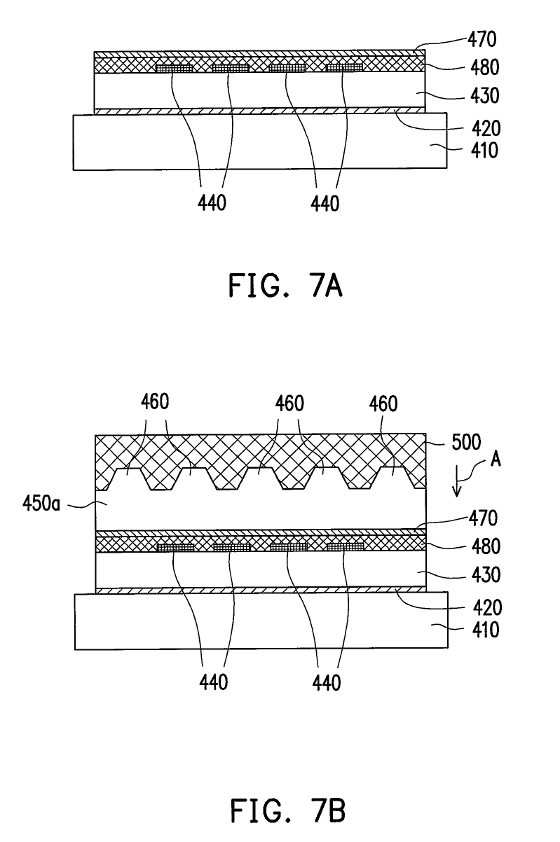

The fifth embodiment is similar to the second embodiment. It is also about the fabricating of the top emission OEL device. FIGS. 7A˜7B are schematic sectional views of a part of the flow of fabricating the OEL device of the fifth embodiment of the present invention. Referring to FIGS. 4A˜4D, FIG. 4F and FIGS. 7A˜7B, firstly, in the fifth embodiment, the steps as shown in FIGS. 4A˜4D are used to fabricate the OEL device having the substrate 410, the first electrode 420, the organic light emitting layer 430 and the second electrode 440.

After the steps of FIGS. 4A˜4D, referring to FIG. 7A, the buffer layer 480 and the anti-oxidation layer 470 are formed in sequence on the second electrode 440, wherein the buffer layer 480 is located between the second electrode 440 and the anti-oxidation layer 470.

The material of the buffer layer 480 is, for example, parylene. Because parylene is relatively rigid, it is difficult to be used to directly fabricate the light enhanced structures 460.

Therefore, referring to FIG. 7B, a polymeric material layer 450a is formed on the anti-oxidation layer 470, and the polymeric material layer 450a is pressed by using a mold 500 along the pressing direction A, such that the polymeric material layer 450a forms the polymeric substrate 450 with the light enhanced structures 460. Moreover, a sealant 490 is also fabricated, so as to form the OEL device 400 with the structure as shown in FIG. 4F.

It should be noted that in the present embodiment, the polymeric material layer 450a is directly formed on the OEL device, and it is pressed to form the polymeric substrate 450 with the light enhanced structures 460. Therefore, each film layer may be combined tightly to prevent the generating of the air gap, so as to improve the light exit efficiency of the OEL device 400. Also, by disposing the anti-oxidation layer 470, the waterproof function of the OEL device 400 is improved.

### The Sixth Embodiment

The sixth embodiment is similar to the fifth embodiment. It is also about the fabricating of the top emission OEL device. The difference of the present embodiment and the fifth embodiment is that in the present embodiment, the anti-oxidation layer 470 is formed on the second surface 454 of the polymeric substrate 450.

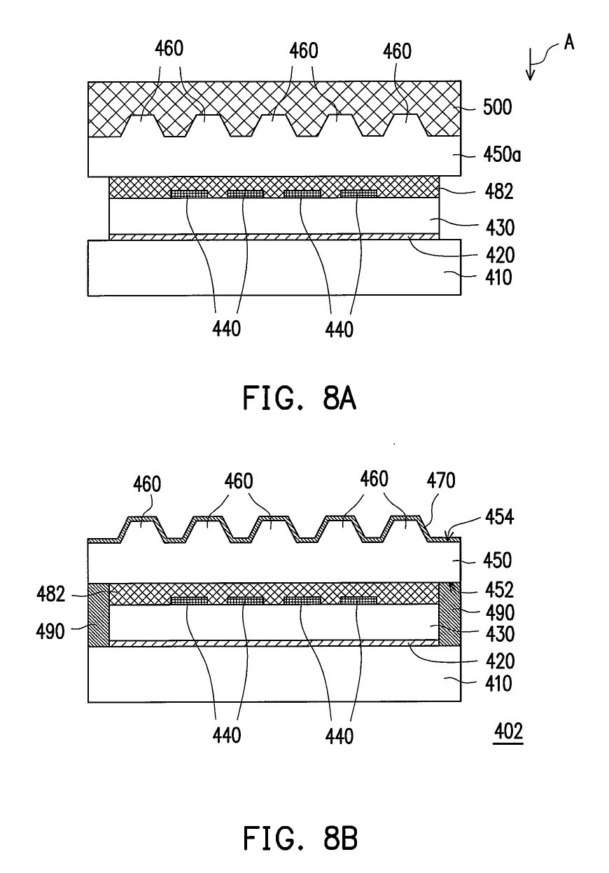

FIGS. 8A˜8B are schematic cross-sectional views of a part of the flow of fabricating the OEL device of the sixth embodiment of the present invention. Referring to FIGS. 4A˜4D and FIGS. 8A˜8B, firstly, in the sixth embodiment, the steps as shown in FIGS. 4A˜4D are also used to fabricate the OEL device having the substrate 410, the first electrode 420, the organic light emitting layer 430 and the second electrode 440.

Then, referring to FIG. 8A, the buffer layer 482 and the polymeric material layer 450a are formed in sequence on the second electrode 440. Then, the polymeric material layer 450a is pressed by using the mold 500 along the pressing direction A, so as to form the polymeric substrate 450 with the light enhanced structures 460 as shown in FIG. 8B.

Next, referring to FIG. 8B, the anti-oxidation layer 470 is formed on the polymeric substrate 450. That is, when the anti-oxidation layer 470 is formed on the second surface 454, the method of fabricating the OEL device further comprises forming a buffer layer 482 between the polymeric substrate 450 and the second electrode 440. The method of forming the buffer layer 482 is, for example, coating method, and the material of the buffer layer 482 is, for example, one selected from oxide, nitride, photo-resist, epoxy, parylene and the combination thereof, or other suitable materials.

Referring to FIG. 8B, the OEL device 402 fabricated by the above steps comprises a substrate 410, a first electrode 420, an organic light emitting layer 430, a second electrode 440, a polymeric substrate 450, a plurality of light enhanced structures 460 and an anti-oxidation layer 470. The first electrode 420 is disposed on the substrate 410. The organic light emitting layer 430 is disposed on the first electrode 420. The second electrode 440 is disposed on the organic light emitting layer 430. The polymeric substrate 450 is disposed above the second electrode 440, the polymeric substrate 450 has a first surface 452 and a second surface 454, and the first surface 452 is opposite to the second electrode 440. The light enhanced structures 460 are disposed on the second surface 454. The anti-oxidation layer 470 is disposed on the second surface 454.

Particularly, in the present invention, when the anti-oxidation layer 470 is disposed on the second surface 454 and covers the light enhanced structures 460, the OEL device 402 further comprises a buffer layer 482 disposed between the polymeric substrate 450 and the second electrode 440. Likewise, as shown in FIG. 8B, the sealant 490 may be used to wrap the organic light emitting layer 430, so as to improve the waterproof function of the OEL device 402.

In each embodiment, the method of providing the polymeric substrate 450 may be that the polymeric substrate 450 with the light enhanced structures 460 is fabricated separately, and then the polymeric substrate 450 is adhered to other film layers; or firstly, the OEL device is fabricated by the steps of FIGS. 4A˜4D, then the polymeric material layer 450a is coated on the OEL device, and the polymeric material layer 450a is pressed by using the mold 500, so as to form the polymeric substrate 450 with the light enhanced structures 460.

Moreover, by disposing the anti-oxidation layer 470, the buffer layer 480 and the buffer layer 482, the fabricating of the OEL device may have preferred waterproof function and better element capability.

To sump up, the OEL device and fabricating method thereof of the present invention comprises the following advantages.

(1) The OEL device adopts the polymeric substrate with the light enhanced structures, thus improving the ray utilization efficiency.

(2) The OEL device has an anti-oxidation layer, thus improving the waterproof function of the OEL device.

(3) In the method of fabricating the OEL device, the polymeric substrate with the light enhanced structures is fabricated by molding method or injection molding method. Therefore, the OEL device may be in mass production so as to lower the production cost.

(4) In the process of the method of fabricating the OEL device, the air gap existing between the film layers may be eliminated, thus improving the light enhanced effect of the OEL device.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An organic electroluminescence (OEL) device, comprising:
a polymeric substrate, having a first surface and a second surface;
a plurality of light enhanced structures, disposed on the first surface of the polymeric substrate;
an anti-oxidation layer, disposed on the second surface of the polymeric substrate;
a first electrode, disposed on the anti-oxidation layer;
an organic light emitting layer, disposed on the first electrode; and
a second electrode, disposed on the organic light emitting layer.

2. The OEL device as claimed in claim 1, wherein the light enhanced structures and the polymeric substrate are integrated as one piece.

3. The OEL device as claimed in claim 1, wherein the material of the anti-oxidation layer is one selected from among oxide, nitride, photo-resist, epoxy, parylene and the combination thereof.

4. The OEL device as claimed in claim 1, wherein the material of the polymeric substrate comprises a moldable polymeric material.

5. The OEL device as claimed in claim 1, wherein the material of the polymeric substrate is one selected from among polymethyl methacrylate (PMMA, acrylic), polydimethylsiloxane (PDMS), polyimide, poly carbonate (PC), polystyrene (PS), polyethylene terephthalate (PET) and the combination thereof.

6. The OEL device as claimed in claim 1, further comprising a protective layer disposed on the second electrode.

7. The OEL device as claimed in claim 6, wherein the material of the protective layer is one selected from among glass, metal, polymer and the combination thereof.

8. The OEL device as claimed in claim 1, further comprising a sealant wrapping the organic light emitting layer.

9. The OEL device as claimed in claim 1, wherein the material of the first electrode comprises the transparent conductive material.

10. The OEL device as claimed in claim 9, wherein the transparent conductive material comprises indium tin oxide (ITO), indium zinc oxide (IZO), or thin-metal with the thickness in nano-scale.

11. The OEL device as claimed in claim 1, wherein the material of the second electrode comprises metal.

12. An organic electroluminescence (OEL) device, comprising:
a substrate;
a first electrode, disposed on the substrate;
an organic light emitting layer, disposed on the first electrode;
a second electrode, disposed on the organic light emitting layer;
a polymeric substrate, disposed above the second electrode, and having a first surface and a second surface, the first surface being opposite to the second electrode;
a plurality of light enhanced structures, disposed on the second surface of the polymeric substrate; and
an anti-oxidation layer, disposed on the first surface of the polymeric substrate or the second surface of the polymeric substrate.

13. The OEL device as claimed in claim 12, wherein the light enhanced structures and the polymeric substrate are integrated as one piece.

14. The OEL device as claimed in claim 12, wherein when the anti-oxidation layer is disposed on the first surface, the OEL further comprises a buffer layer disposed between the anti-oxidation layer and the second electrode.

15. The OEL device as claimed in claim 14, wherein the material of the buffer layer is one selected from among oxide, nitride, photo-resist, epoxy, parylene and the combination thereof.

16. The OEL device as claimed in claim 12, wherein when the anti-oxidation layer is disposed on the second surface and covers the light enhanced structures, the polymeric substrate is located on the second electrode.

17. The OEL device as claimed in claim 12, wherein when the anti-oxidation layer is disposed on the second surface and covers the light enhanced structures, the OEL further comprises a buffer layer disposed between the polymeric substrate and the second electrode.

18. The OEL device as claimed in claim 17, wherein the material of the buffer layer is one selected from among oxide, nitride, photo-resist, epoxy, parylene and the combination thereof.

19. The OEL device as claimed in claim 12, wherein the material of the anti-oxidation layer is one selected from among oxide, nitride, photo-resist, epoxy, parylene and the combination thereof.

20. The OEL device as claimed in claim 12, wherein the material of the polymeric substrate comprises a moldable polymeric material.

21. The OEL device as claimed in claim 12, wherein the material of the polymeric substrate is one selected from among polymethyl methacrylate (PMMA, acrylic), polydimethylsiloxane (PDMS), polyimide, poly carbonate (PC), polystyrene (PS), polyethylene terephthalate (PET) and the combination thereof.

22. The OEL device as claimed in claim 12, further comprising a sealant wrapping the organic light emitting layer.

23. The OEL device as claimed in claim 12, wherein the material of the first electrode comprises metal.

24. The OEL device as claimed in claim 12, wherein the material of the second electrode comprises the transparent conductive material.

25. The OEL device as claimed in claim 24, wherein the transparent conductive material comprises indium tin oxide (ITO), indium zinc oxide (IZO), or thin-metal with the thickness in nano-scale.

26. A method of fabricating an organic electroluminescence (OEL) device, comprising:
providing a polymeric substrate having a first surface and a second surface, wherein a plurality of light enhanced structures is formed on the first surface;
forming an anti-oxidation layer on the second surface;
forming a first electrode on the anti-oxidation layer;
forming an organic light emitting layer on the first electrode; and
forming a second electrode on the organic light emitting layer.

27. The method of fabricating an OEL device as claimed in claim 26, wherein the method of forming the light enhanced structures on the first surface comprises molding method or injection molding method.

28. The method of fabricating an OEL device as claimed in claim 26, wherein the method of forming the anti-oxidation layer on the second surface comprises coating method or evaporation method.

29. The method of fabricating an OEL device as claimed in claim 26, further comprising forming a protective layer on the second electrode.

30. The method of fabricating an OEL device as claimed in claim 26, further comprising providing a sealant to wrap the organic light emitting layer.

31. A method of fabricating an organic electroluminescence (OEL) device, comprising:
providing a substrate;
forming a first electrode on the substrate;
forming an organic light emitting layer on the first electrode;
forming a second electrode on the organic light emitting layer;
providing a polymeric substrate disposed above the second electrode, wherein the polymeric substrate has a first surface and a second surface, the first surface is opposite to the second electrode, and a plurality of light enhanced structures is formed on the second surface; and
forming an anti-oxidation layer on the first surface or the second surface.

32. The method of fabricating an OEL device as claimed in claim 31, wherein the method of providing the polymeric substrate comprises:
forming a polymeric material layer on the substrate; and
pressing the polymeric material layer with a mold to form the light enhanced structures on the second surface.

33. The method of fabricating an OEL device as claimed in claim 31, wherein when the anti-oxidation layer is formed on the first surface, the method further comprises forming a buffer layer between the anti-oxidation layer and the second electrode.

34. The method of fabricating an OEL device as claimed in claim 31, wherein when the anti-oxidation layer is formed on the second surface, the polymeric substrate is directly disposed on the second electrode.

35. The method of fabricating an OEL device as claimed in claim 31, wherein when the anti-oxidation layer is formed on the second surface, the method further comprises forming a buffer layer between the polymeric substrate and the second electrode.

36. The method of fabricating an OEL device as claimed in claim 31, further comprising providing a sealant to wrap the organic light emitting layer.
